(19) United States
(12) Patent Application Publication
(10) Pub. No.: US 2005/0179117 A1
(43) Pub. Date: Aug. 18, 2005

(54) Composition of dielectric for plasma display panel

(75) Inventor: Sung-Wook Lee, Gwacheon (KR)

Correspondence Address: FLESHNER & KIM, LLP, P.O. BOX 221200, CHANTILLY, VA, 20153, US

(73) Assignee: LG Electronics

(21) Appl. No.: 10/992,078

(22) Filed: Nov. 19, 2004

(30) Foreign Application Priority Data
Feb. 18, 2004 (KR) 10795/2004

(51) Int. Cl. H01L 23/58

(52) U.S. Cl. 257/650

(57) ABSTRACT

A composition of a dielectric for a plasma display panel can prevent colloid generation and yellowing. To this end, the composition of a dielectric for the plasma display panel is composed of transition-metal oxide such as cobalt oxide (CoO) or copper oxide (CuO).

### BACKGROUND OF THE INVENTION

1. Field of the Invention

The present invention relates to a plasma display panel, and particularly, to a composition of a dielectric for a plasma display panel.

2. Description of the Prior Art

In general, a plasma display panel (PDP) device is receiving much attention as a next generation display together with a thin film transistor (TFT), a liquid crystal display (LCD), an EL (Electro-Luminescence) device, and a FED (Field Emission Display) and the like.

The plasma display panel (PDP) device is a display device using a luminescent phenomena according to an energy difference made when red, green and blue fluorescent materials are changed from an excited state to a ground state after being excited by 147 nm of ultraviolet rays which are generated as a He+X3 gas or N3+X3 gas is discharged from a discharging cell isolated by a barrier rib.

The plasma display panel device is anticipated to occupy large-scale display markets because of its advantages such as facilitation in manufacturing based on its simple structure, a high brightness, a high luminous efficacy, a memory function, a high nonlinearity, a 160° or more optical angular field and the like.

A structure of a plasma display panel in accordance with the related art will now be described with reference to FIG. 1.

FIG. 1 is a sectional view showing a structure of a plasma display panel in accordance with the related art.

As shown, the plasma display panel in accordance with the related art includes: a lower glass substrate 21; a lower insulation layer 20 formed on the lower glass substrate 21; an address electrode 22 formed on the lower insulation layer 20; a lower dielectric layer 19 formed on the address electrode 22 and the lower insulation layer 20; an isolation wall 17 defined on the lower dielectric layer 19 in order to divide each discharging cell; a black matrix layer 16 formed on the isolation wall 17; a fluorescent layer 18 formed with a certain thickness on the side of the black matrix layer 16 and the isolation wall 17 and on the lower dielectric layer 19 and emitting red, green and blue visible rays by the ultraviolet rays; an upper glass substrate 11; a sustain electrode 12 formed on one portion of the upper glass substrate in a manner of crossing the address electrode 22 at a right angle; a bus electrode 13 formed on one portion of the sustain electrode 12; an upper dielectric layer 14 formed on the bus electrode 13, the sustain electrode 12 and the upper glass substrate 11; and a protection layer (MgO) 15 formed on the upper dielectric layer 14 in order to protect the upper dielectric layer 14. Hereinafter, the structure of the plasma display panel in accordance with the related art will now be described.

First, a high strain point glass substrate is used as the upper glass substrate 11 and the lower glass substrate 21 of the plasma display panel. The lower insulation layer 20 is positioned on the lower glass substrate 21, the high strain point glass substrate, and the address electrode 22 is positioned on the lower insulation layer 20.

The lower dielectric layer 19 positioned on the address electrode 22 and the lower insulation layer 20 blocks visible rays emitted toward the lower glass substrate 21. In addition, in order to improve luminous efficacy, a dielectric layer having high reflectance is used as the lower dielectric layer 19. The lower dielectric layer 19 is an opaque dielectric layer with 60% or more of reflectance, thereby minimizing light loss.

The sustain electrode 12 positioned in a manner of crossing the address electrode 22 perpendicularly and a bus electrode 13 positioned on the sustain electrode 12 are formed under the upper glass substrate 11, the high strain point glass substrate. The upper dielectric layer 14 is positioned on the bus electrode 13. In addition, in order to prevent the upper dielectrode layer 14 from being damaged by plasma generation, the protection layer 15 is positioned on the upper dielectric layer 14. Here, because the upper dielectric layer 14 is directly in contact with the sustain electrode 12 and the bus electrode 13, the upper dielectric layer 14 should have a high softening temperature in order to avoid a chemical reaction with the sustain electrode 12 and the bus electrode 13.

The fluorescent layer 18 is formed by laminating fluorescent materials in a sequential order of red, green and blue and emits a specific wavelengths of visible rays depending on intensity of ultraviolet rays according to plasma generated in a region between the isolation walls 17.

Meanwhile, a main constituent of the bus electrode 13 of the plasma display panel is Ag (silver), and an upper dielectric layer 14 is formed on the bus electrode 13, the sustain electrode 12 and the upper glass substrate 11. The upper dielectric layer 14 is formed by applying a dielectric material on the exposed bus electrode 13, the exposed sustain electrode 12 and the exposed upper glass substrate 11 and then baking the applied dielectric material at a temperature of about 500˜600° C. Ag ions generated when the bus electrode 13 is formed are diffused into the upper dielectric layer 14 in the baking process, thereby forming circular Ag colloids in the upper dielectric layer 14.

FIG. 2 is a view showing shapes 100 of Ag colloids formed in the upper dielectric layer 14 of FIG. 1.

As shown, because Ag⁺ is generated from the bus electrode 13, the circular Ag colloids 100 are formed around the bus electrode 13 and in the upper dielectric layer 14, and the circular Ag colloids visually appear in yellow. Namely, it has been known that yellowing occurs in the plasma display panel using the bus electrode 13 having Ag as the main constituent.

The yellowing means that Ag ions diffused in a process of forming the upper dielectric layer 14 on the bus electrode 13 are decreased by generating Ag colloids. Such yellowing lowers a color temperature of full-white images and deteriorates image quality when the plasma display panel is driven.

A composition of the upper dielectric layer 14 in which the yellowing commonly occurs, is usually composed of glass powder of a PbO—B₂O₃—SIO₂ group, alkaline earth RO (e.g., at least one of BaO, MgO, SrO), and Al₂O₃. Namely, the Ag ions diffused from the bus electrode 13 are coupled to ambient electrons, thereby forming Ag colloids in the upper dielectric layer 14.

In order to prevent the yellowing, a minimum amount of PbO is contained in dielectric materials of the upper dielectric layer 14 or a composition of a dielectric without PbO is used to thereby prevent diffusion of Ag ions in the upper dielectric layer 14. However, despite such an effort, generation of a circular Ag colloid cannot be completely prevented. In addition, if a minimum amount of PbO is contained in dielectric materials of the upper dielectric layer 14 or a dielectric composition without PbO is used, conditions of a process for manufacturing the upper dielectric layer 14 are changed, baking conditions, a baking temperature or the like is changed according to the changes in process condition. However, it is difficult to create new processes whenever the conditions of the corresponding processes are changed in order to prevent the yellowing.

As so far described, the plasma display panel in accordance with the related art has a problem in that yellowing is caused around the bus electric, and a color temperature of images is deteriorated because Ag ions diffused from an Ag electrode generate circular colloids in a process of forming the upper dielectric layer on the bus electrode (Ag electrode).

In addition, in order to prevent Ag colloid generation, a baking condition, a baking temperature or the like is changed by limiting a dielectric material of the upper dielectric layer or changing process conditions. However, it is difficult to create new processes whenever conditions for a corresponding process are changed to prevent the yellowing.

Meanwhile, plasma display panels and their manufacturing methods according to another related arts are disclosed in detail in the U.S. Pat. No. 5,838,106 issued on Sep. 17, 1998, the U.S. Pat. No. 6,242,859 issued on Jun. 5, 2001, and the U.S. Pat. No. 6,599,851 issued on Jul. 29, 2003.

### SUMMARY OF THE INVENTION

Therefore, an object of the present invention is to provide a composition of a dielectric for a plasma display panel capable of preventing colloid generation by adding transition-metal oxide such as cobalt oxide (CoO) or copper oxide (CuO) to a composition of a dielectric.

Another object of the present invention is to provide a composition of a dielectric for a plasma display panel capable of preventing yellowing by adding blueish or greenish transition-metal oxide such as cobalt oxide (CoO) or copper oxide (CuO).

To achieve these and other advantages and in accordance with the purpose of the present invention, as embodied and broadly described herein, there is provided a composition of a dielectric for a plasma display panel comprising: glass powder; and transition-metal oxide.

To achieve these and other advantages and in accordance with the purpose of the present invention, as embodied and broadly described herein, there is provided a composition of a dielectric for a plasma display panel comprising: glass powder of a PbO—B₂O₃—SiO₂ group; at least one of BaO, MgO and SrO; Al₂O₃; and one of CoO and CuO.

To achieve these and other advantages and in accordance with the purpose of the present invention, as embodied and broadly described herein, there is provided a composition of a dielectric for a plasma display panel comprising: glass powder of a PbO—B₂O₃—SiO₂ group; at least one of BaO, MgO and SrO; Al₂O₃; and CoO, wherein CoO is 0.01 wt %˜10 wt %.

To achieve these and other advantages and in accordance with the purpose of the present invention, as embodied and broadly described herein, there is provided a composition of a dielectric for a plasma display panel comprising: glass powder of a PbO—B₂O₃—SiO₂ group; at least one of BaO, MgO and SrO; Al₂O₃; and CuO, wherein CuO is 0.01 wt %˜10 wt %.

To achieve these and other advantages and in accordance with the purpose of the present invention, as embodied and broadly described herein, there is provided a composition of an upper dielectric for a plasma display panel comprising: glass powder of a PbO—B₂O₃—SiO₂ group; at least one of BaO, MgO and SrO; Al₂O₃; and one of CoO and CuO, wherein CoO or CuO is 0.01 wt %˜10 wt %.

To achieve these and other advantages and in accordance with the purpose of the present invention, as embodied and broadly described herein, there is provided a composition of a dielectric layer for a plasma display panel including a substrate; a first electrode formed on one portion of the substrate; a second electrode formed on one portion of the first electrode; and a dielectric layer formed on the first electrode, the second electrode and the substrate, comprising: glass powder; and transition-metal oxide.

To achieve these and other advantages and in accordance with the purpose of the present invention, as embodied and broadly described herein, there is provided a composition of an upper dielectric layer for a plasma display panel including an upper glass substrate; a sustain electrode formed on one portion of the upper glass substrate; a bus electrode formed on one portion of the sustain electrode; and an upper dielectric layer formed on the sustain electrode, the bus electrode and the upper glass substrate, comprising: glass powder of a PbO—B₂O₃—SiO₂ group; and one of CoO and CuO.

To achieve these and other advantages and in accordance with the purpose of the present invention, as embodied and broadly described herein, there is provided a composition of an upper dielectric layer for a plasma display panel including: a lower glass substrate; a lower insulation layer formed on the lower glass substrate; an address electrode formed on the lower insulation layer; a lower dielectric layer formed on the address electrode and the lower insulation layer; an isolation wall defined on the lower dielectric layer to divide each discharging cell; a black matrix layer formed on the isolation wall; a fluorescent layer formed with a predetermined thickness on the side of the black matrix layer and the isolation wall and on the lower dielectric layer and emitting red, green and blue visible rays upon receiving ultraviolet rays; an upper glass substrate; a sustain electrode formed on the upper glass substrate in a manner of crossing the address electrode perpendicularly; a bus electrode formed on the sustain electrode and having Ag as a main constituent; an upper dielectric layer formed on the bus electrode, the sustain electrode and the upper glass substrate; and a protection layer formed on the upper dielectric layer to protect the upper dielectric layer, comprising: glass powder; and one of CoO and CuO.

The foregoing and other objects, features, aspects and advantages of the present invention will become more apparent from the following detailed description of the present invention when taken in conjunction with the accompanying drawings.

### BRIEF DESCRIPTION OF THE DRAWINGS

The accompanying drawings, which are included to provide a further understanding of the invention and are incorporated in and constitute a unit of this specification, illustrate embodiments of the invention and together with the description serve to explain the principles of the invention.

In the drawings:

FIG. 1 is a sectional view showing a structure of a plasma display panel in accordance with the related art;

FIG. 2 is a view showing shapes of Ag colloids formed in an upper dielectric layer of FIG. 1;

FIG. 3 is a sectional view of a plasma display panel using a dielectric composition in accordance with an embodiment of the present invention; and

FIG. 4 is a sectional view showing an upper plate of a plasma display panel using an upper dielectric layer in accordance with an embodiment of the present invention.

### DETAILED DESCRIPTION OF THE PREFERRED EMBODIMENTS

Reference will now be made in detail to the preferred embodiments of the present invention, examples of which are illustrated in the accompanying drawings.

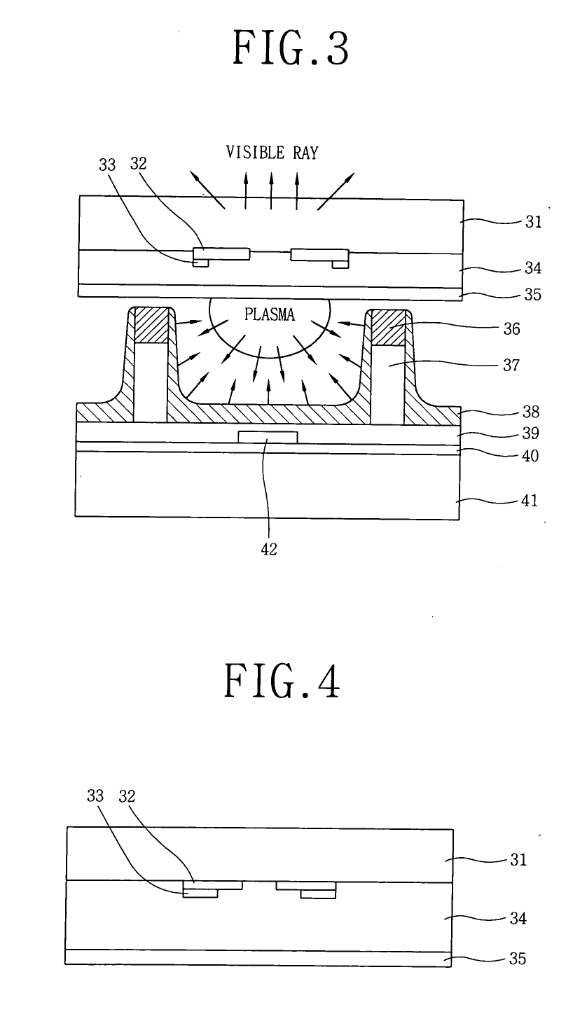

Hereinafter, a composition of a dielectric for a plasma display panel capable of preventing colloid generation and yellowing by adding transition-metal oxide such as cobalt oxide (CoO) or copper oxide (CuO) to a dielectric composition in accordance with preferred embodiments of the present invention will now be described with reference to FIGS. 3 and 4.

FIG. 3 is a sectional view of a plasma display panel using a composition of a dielectric in accordance with an embodiment the present invention.

As shown, the plasma display panel using a dielectric composition in accordance with an embodiment of the present invention includes: a lower glass substrate 41; a lower insulation layer 40 formed on the lower glass substrate 41; an address electrode 42 formed on the lower insulation layer 40; a lower dielectric layer 39 formed on the address electrode 42 and the lower insulation layer 40; an isolation wall 37 defined on the lower dielectric layer 39 in order to divide each discharging cell; a black matrix layer 36 formed on the isolation wall 37; a fluorescent layer 38 formed with a certain thickness on the side of the black matrix layer 36 and the isolation wall 37 and on the lower dielectric layer 39 and emitting red, green and blue visible rays by ultraviolet rays; an upper glass substrate 31; a sustain electrode 32 formed on one portion of the upper glass substrate 31 in a manner of crossing the address electrode 42 perpendicularly; a bus electrode 33 formed on one portion of the sustain electrode 32; an upper dielectric layer 45 formed on the bus electrode 33, the sustain electrode 32 and the upper glass substrate 31 and having transition-metal oxide; and a protection layer (MgO) 35 formed on the upper dielectric layer 34 to protect the upper dielectric layer 34. Namely, because the structures of the plasma display panel in accordance with the present invention except the upper dielectric layer 34 are the same as the related art, detailed explanations thereon will be omitted.

An upper plate of a plasma display panel using an upper dielectric layer 34 in accordance with an embodiment of the present invention will now be described in detail with reference to FIG. 4.

FIG. 4 is a sectional view showing the upper plate of the plasma display panel using an upper dielectric layer in accordance with an embodiment of the present invention.

As shown therein, the upper plate of the plasma display panel using the upper dielectric layer 34 in accordance with the present invention includes an upper glass substrate 31; a sustain electrode 32 formed on one portion of the upper glass substrate 31; a bus electrode 33 formed on one portion of the sustain electrode 32 and having Ag as a main constituent; an upper dielectric layer 34 formed on the bus electrode 33, the sustain electrode 32 and the upper glass substrate 31 and containing at least one of CoO and CuO, transition-metal oxide; and a protection layer (MgO) 35 formed on the upper dielectric layer 34 to protect the upper dielectric layer 34. The composition of the upper dielectric layer 34 is composed of glass powder of a PbO—B₂O₃—SiO₂ group, alkaline earth RO (e.g., at least one of BaO, MgO, SrO), and at least one of Al₂O₃, CoO and CuO. Here, 0.01 wt %˜10 wt % of CoO or CuO is added to the composition of the upper dielectric layer 34.

For example, if 0.01 wt %˜10 wt % of CoO or CuO is added to the composition of the upper dielectric layer 34, Ag colloid generation due to Ag ions (Ag⁺) diffused in a process of baking the upper dielectric layer 34 (heat treatment at the temperature of 500˜600° C.) is prevented. Namely, because transition-metal oxide is reduced earlier than Ag ions, Ag ions reduced into Ag⁰ by being coupled to ambient electrons under reduction conditions are decreased in number, and electrons around the bus electrode is decreased in number. Accordingly, Ag colloids are not generated. In addition, even if fine Ag colloids are generated in the upper dielectric layer 34, the yellowing can be prevented by the color of the bluish or greenish transition-metal oxide.

Hereinafter, the upper dielectric layer 34 will now be described in detail.

First, transition-metal oxide such as CoO or CuO which is reduced earlier than Ag ions (Ag⁺) of the bus electrode 33 whose main constituent is Ag is added to a glass composition (glass powder of a PbO—B₂O₃—SiO₂ group) of the upper dielectric layer 34. Here, CoO and CuO may be added to the upper dielectric layer 34.

If the transition-metal oxide such as CoO or CuO is contained in a glass composition of the upper dielectric layer 34, transition-metal ions are reduced into Co³⁺→Co²⁺ or Cu³⁺→Cu²⁺ by a change of valence electrons of the transition-metal ions before Ag⁺ is reduced, thereby decreasing the number of electrons around Ag⁺. Therefore, reduction of Ag ions (Ag⁺) can be prevented.

In addition, the upper dielectric layer 34 to which CoO or CuO is added is blueish or greenish, and the blueish color or the greenish color functions as a complementary color of yellow and also provides high image quality by raising a color temperature. Namely, by adding the blueish or greenish transition-metal oxide to a composition of an upper dielectric layer 34, a color temperature is raised and image quality is improved.

Meanwhile, the amount of CoO or CuO added to the composition of the upper dielectric layer 34 can be varied according to a process for preventing the yellowing, a correlation of coloring of transition-metal oxide, conditions of manufacturing processes of the upper dielectric layer 34.

As so far described, the composition of the dielectric of the plasma display panel in accordance with the present invention contains at least one of CoO and CuO, transition-metal oxide, so that the transition-metal ions are reduced first before Ag ions diffused into the composition are reduced. Accordingly, Ag colloid generation can be prevented.

In addition, the upper dielectric layer of the plasma display panel in accordance with the present invention contains at least one of CoO and CuO, blueish or greenish transition-metal oxide, so that yellowing is prevented by the color of the transition-metal oxide and a color temperature is raised to improve image quality.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalence of such metes and bounds are therefore intended to be embraced by the appended claims.

1. A composition of a dielectric for a plasma display panel comprising:
glass powder; and
transition-metal oxide.

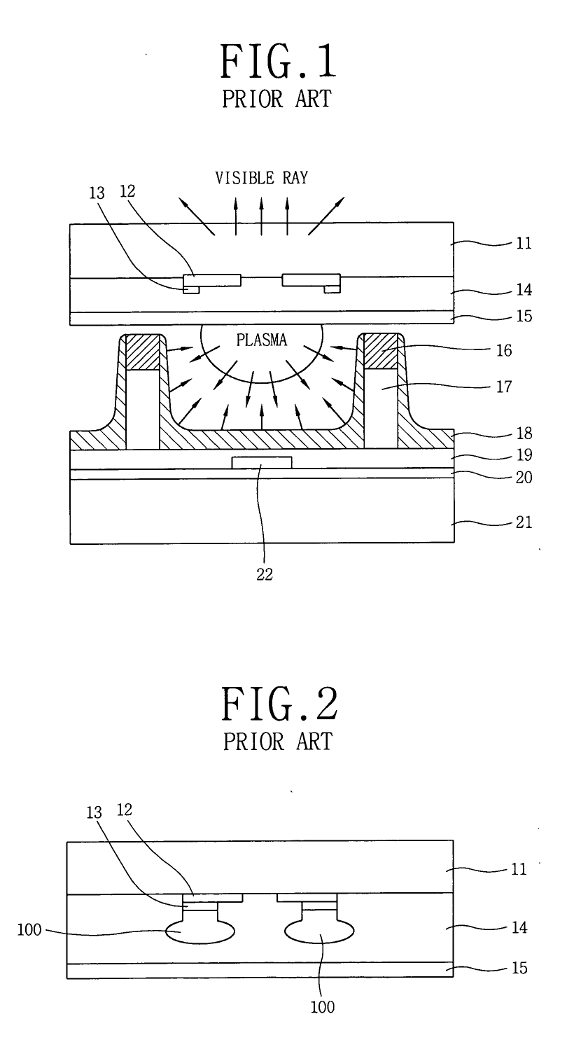

2. The composition of FIG. 1, wherein the transition-metal oxide is CoO or CuO, and an amount of CoO or CuO is in a range of 0.01 wt % to 10 wt %.

3. A composition of a dielectric for a plasma display panel comprising:
glass powder of a PbO—B₂O₃—SiO₂ group;
at least one of BaO, MgO and SrO;
Al₂O₃; and
one of CoO and CuO.

4. A composition of a dielectric for a plasma display panel comprising:
glass powder of a PbO—B₂O₃—SiO₂ group;
at least one of BaO, MgO and SrO;
Al₂O₃; and
CoO, wherein an amount of CoO is in a range of 0.01 wt % to 10 wt %.

5. A composition of a dielectric for a plasma display panel comprising:
glass powder of a PbO—B₂O₃—SiO₂ group;
at least one of BaO, MgO and SrO;
Al₂O₃; and
CuO, wherein CuO is 0.01 wt %˜10 wt %.

6. A composition of an upper dielectric for a plasma display panel comprising:
glass powder of a PbO—B₂O₃—SiO₂ group;
at least one of BaO, MgO and SrO;
Al₂O₃; and
one of CoO and CuO, wherein an amount of CoO or CuO is 0.01 wt %˜10 wt %.

7. A composition of a dielectric layer for a plasma display panel including a substrate; a first electrode formed on one portion of the substrate; a second electrode formed on one portion of the first electrode; and a dielectric layer formed on the first electrode, the second electrode and the substrate, comprising:
glass powder; and
transition-metal oxide.

8. The composition of claim 7, wherein the transition-metal oxide is CoO or CuO, and an amount of CoO or CuO is 0.01 wt %˜10 wt %.

9. The composition of claim 7, wherein the glass powder is glass powder of a PbO—B₂O₃—SiO₂ group.

10. The composition of claim 9, further comprising at least one of BaO, MgO and SrO.

11. The composition of claim 10, further comprising Al₂O₃.

12. A composition of an upper dielectric layer for a plasma display panel including an upper glass substrate; a sustain electrode formed on one portion of the upper glass substrate; a bus electrode formed on one portion of the sustain electrode; and an upper dielectric layer formed on the sustain electrode, the bus electrode and the upper glass substrate, comprising:
glass powder of a PbO—B₂O₃—SiO₂ group; and
one of CoO and CuO.

13. The composition of claim 12, wherein an amount of CoO or CuO is 0.01 wt %˜10 wt %.

14. The composition of claim 12, further comprising at least one of BaO, MgO and SrO.

15. The composition of claim 12, further comprising Al₂O₃.

16. A composition of an upper dielectric layer for a plasma display panel including: a lower glass substrate; a lower insulation layer formed on the lower glass substrate; an address electrode formed on the lower insulation layer; a lower dielectric layer formed on the address electrode and the lower insulation layer; an isolation wall defined on the lower dielectric layer to divide each discharging cell; a black matrix layer formed on the isolation wall; a fluorescent layer formed with a predetermined thickness on the side of the black matrix layer and the isolation wall and on the lower dielectric layer and emitting red, green and blue visible rays upon receiving ultraviolet rays; an upper glass substrate; a sustain electrode formed on the upper glass substrate in a manner of crossing the address electrode perpendicularly; a bus electrode formed on the sustain electrode and having Ag as a main constituent; an upper dielectric layer formed on the bus electrode, the sustain electrode and the upper glass substrate; and a protection layer formed on the upper dielectric layer to protect the upper dielectric layer, comprising:
glass powder; and
one of CoO and CuO.

17. The composition of claim 16, wherein an amount of CoO or CuO is 0.01 wt %˜10 wt %.

18. The composition of claim 16, wherein the glass powder is a PbO—B₂O₃—SiO₂ group.

19. The composition of claim 16, further comprising at least one of BaO, MgO and SrO.

20. The composition of claim 16, further comprising Al₂O₃.
